(19) United States
(12) Patent Application Publication
(10) Pub. No.: US 2015/0364499 A1
(43) Pub. Date: Dec. 17, 2015

(54) SUBSTRATE STRUCTURE AND MANUFACTURING METHOD THEREOF

(71) Applicant: E Ink Holdings Inc., Hsinchu (TW)

(72) Inventors: Kuan-Yi Lin, Hsinchu (TW); Po-Hsin Lin, Hsinchu (TW); Fang-An Shu, Hsinchu (TW); Cheng-Hang Hsu, Hsinchu (TW); Tzung-Wei Yu, Hsinchu (TW)

(21) Appl. No.: 14/666,314

(22) Filed: Mar. 24, 2015

(30) Foreign Application Priority Data
Jun. 16, 2014 (TW) 103120716

(51) Int. Cl. H01L 27/12; H01L 29/49

(52) U.S. Cl. CPC H01L 27/1218; H01L 27/1222; H01L 27/124; H01L 27/1255; H01L 27/1259; H01L 29/4908

(57) ABSTRACT

A substrate structure including a flexible substrate, a gate line, a gate, an inorganic insulation layer, a semiconductor layer, a source, a drain, an inorganic passivation layer and an organic insulation layer is provided. The gate is electrically connected to the gate line. The inorganic insulation layer covers the gate and exposes a portion of the flexible substrate. The semiconductor layer is disposed on the inorganic insulation layer and disposed corresponding to the gate. The source and the drain extend from the inorganic insulation layer to the semiconductor layer and expose a portion of the semiconductor layer. The inorganic passivation layer covers portions of the source and the drain and directly contacts to the semiconductor layer exposed by the source and the drain. The organic insulation layer covers the source, the drain, the inorganic passivation layer and the flexible substrate exposed by the inorganic insulation layer.

### CROSS-REFERENCE TO RELATED APPLICATION

This application claims the priority benefit of Taiwan application serial no. 103120716, filed on Jun. 16, 2014. The entirety of the above-mentioned patent application is hereby incorporated by reference herein and made a part of this specification.

### BACKGROUND OF THE INVENTION

1. Field of the Invention

The invention relates to a substrate structure and a manufacturing method thereof, and particularly relates to a substrate structure with the feature of flexible and a manufacturing method thereof.

2. Description of Related Art

Generally, a thin-film transistor at least has a gate, a source, a drain, a channel layer, etc., wherein a voltage of the gate can be controlled to change conductivity of the channel layer, such that the source and the drain present a conduction (turn-on) state or an insulation (turn-off) state there between. Moreover, an N-doped or P-doped ohmic contact layer is generally formed on the channel layer to decrease a contact resistance between the channel layer and the source or between the channel layer and the drain. In the conventional thin-film transistor, a material of the channel layer is generally amorphous silicon (a-Si) or poly-silicon (p-Si).

For example, during a manufacturing process of the thin-film transistor using the a-Si channel layer (which is referred to as a-Si thin-film transistor hereinafter), a gate insulation layer and a passivation layer using an inorganic material are generally used to cover upper and lower sides of the a-Si semiconductor channel layer. In detail, besides covering the gate, the gate insulation layer also completely covers a configuration surface of a flexible substrate, and besides covering the a-Si semiconductor channel layer, the passivation layer also completely covers the gate insulation layer, the source and the drain. In other words, the gate insulation layer and the passivation layer using the inorganic material are all comprehensive film layers. Since the inorganic material is inflexible, when the a-Si thin-film transistor is bended, it is probably cracked, such that vapor and oxygen may enter the a-Si semiconductor channel layer to influence reliability and service life of the components therein.

### SUMMARY OF THE INVENTION

The invention is directed to a substrate structure and a manufacturing method thereof, by which a problem that the conventional a-Si thin-film transistor is easy to be cracked when it is bended is avoided, so as to achieve higher structure reliability.

The invention provides a substrate structure including a flexible substrate, a gate line, a gate, an inorganic insulation layer, a semiconductor layer, a source, a drain, an inorganic passivation layer and an organic insulation layer. The gate line is disposed on the flexible substrate. The gate is electrically connected to the gate line and is disposed on the flexible substrate. The inorganic insulation layer is disposed on the flexible substrate and covers the gate and exposes a portion of the flexible substrate. The semiconductor layer is disposed on the inorganic insulation layer and disposed corresponding to the gate. The source and the drain extend from the inorganic insulation layer to the semiconductor layer, where the source and the drain expose a portion of the semiconductor layer. The inorganic passivation layer is disposed on the source and the drain and covers a portion of the source and a portion of the drain, and directly contacts the semiconductor layer exposed by the source and the drain. The organic insulation layer is disposed on the flexible substrate and covers the source, the drain, the inorganic passivation layer and the flexible substrate exposed by the inorganic insulation layer.

In an embodiment of the invention, the substrate structure further includes a capacitor unit disposed on the flexible substrate. The capacitor unit includes a first conductive layer, an insulation layer and a second conductive layer. The first conductive layer and the gate belong to a same film layer. The insulation layer and the inorganic insulation layer belong to a same film layer. The second conductive layer and the source and the drain belong to a same film layer. The organic insulation layer covers the capacitor unit.

In an embodiment of the invention, the organic insulation layer has at least one first opening, at least one second opening and at least one third opening. The first opening exposes a portion of the source, the second opening exposes a portion of the drain, and the third opening exposes a portion of the second conductive layer.

In an embodiment of the invention, the substrate structure further includes a tracing layer, an organic isolation layer and a pixel electrode. The tracing layer is disposed on the organic insulation layer, where the tracing layer is electrically connected to the source, the drain and the second conductive layer through the first opening, the second opening and the third opening of the organic insulation layer. The organic isolation layer is disposed on the organic insulation layer and covers the organic insulation layer and the tracing layer. The organic isolation layer has at least one contact opening, and the contact opening is disposed corresponding to the capacitor unit, and exposes a portion of the tracing layer. The pixel electrode is disposed on the organic isolation layer, where the pixel electrode is electrically connected to the tracing layer through the contact opening of the organic isolation layer.

In an embodiment of the invention, the organic insulation layer has at least one first opening and at least one second opening. The first opening exposes a portion of the source, and the second opening exposes a portion of the drain.

In an embodiment of the invention, the substrate structure further includes a tracing layer and a capacitor unit. The tracing layer is disposed on the organic insulation layer, where the tracing layer is electrically connected to the source and the drain through the first opening and the second opening of the organic insulation layer. The capacitor unit is disposed on the flexible substrate, and includes a first conductive layer, an insulation layer and a second conductive layer. The first conductive layer and the gate belong to a same film layer, the insulation layer and the organic insulation layer belong to a same film layer, and the second conductive layer and the tracing layer belong to a same film layer.

In an embodiment of the invention, the organic insulation layer covers the gate line.

In an embodiment of the invention, the semiconductor layer includes a channel layer and an ohmic contact layer located on the channel layer. The ohmic contact layer exposes a portion of the channel layer.

The invention provides a manufacturing method of a substrate structure, which includes following steps. A gate electrically connected to a gate line, an inorganic insulation material layer and a semiconductor material layer are sequentially formed on a flexible substrate. The inorganic insulation material layer completely covers the gate and the flexible substrate, and the semiconductor material layer is disposed corresponding to the gate. A source and a drain are formed on the organic insulation material layer. The source and the drain extend from the inorganic insulation material layer to the semiconductor material layer, and the source and the drain expose a portion of the semiconductor material layer and a portion of the inorganic insulation material layer. The portion of the semiconductor material layer exposed by the source and the drain is removed to define a semiconductor layer. An inorganic passivation layer is formed on the source and the drain, where the inorganic passivation layer covers a portion of the source and a portion of the drain, and directly contacts the semiconductor layer. After the inorganic passivation layer is formed, the inorganic insulation material layer is removed to expose a portion of the flexible substrate and define an inorganic insulation layer. An organic insulation layer is formed on the flexible substrate, where the organic insulation layer covers the source, the drain, the inorganic passivation layer and the flexible substrate exposed by the inorganic insulation layer.

In an embodiment of the invention, the step of forming the inorganic passivation layer on the source and the drain includes following steps. An inorganic passivation material layer is formed on the source and the drain, where the inorganic passivation material layer covers the source, the drain, the semiconductor layer exposed by the source and the drain and a portion of the inorganic insulation material layer. A portion of the inorganic passivation material layer is removed to form the inorganic passivation layer.

In an embodiment of the invention, the manufacturing method of the substrate structure further includes following steps. When the gate is formed, a first conductive layer is simultaneously formed, where the inorganic insulation material layer covers the first conductive layer, and the first conductive layer and the gate belong to a same film layer. When the source and the gate are formed, a second conductive layer is simultaneously formed, where the second conductive layer is located on the inorganic insulation material layer, and the second conductive layer and the source and the drain belong to a same film layer. When the inorganic insulation material layer exposed by the source and the drain is removed, an insulation layer is further defined, where the insulation layer is located between the first conductive layer and the second conductive layer, and the first conductive layer, the insulation layer and the second conductive layer define a capacitor unit. When the organic insulation layer is formed on the flexible substrate, the organic insulation layer covers the capacitor unit.

In an embodiment of the invention, the manufacturing method of the substrate structure further includes following steps. After the organic insulation layer is formed, a portion of the organic insulation layer is removed to form at least one first opening, at least one second opening and at least one third opening, where the first opening exposes a portion of the source, the second opening exposes a portion of the drain, and the third opening exposes a portion of the second conductive layer.

In an embodiment of the invention, the manufacturing method of the substrate structure further includes following steps. After a portion of the organic insulation layer is removed, a tracing layer is formed on the organic insulation layer, where the tracing layer is electrically connected to the source, the drain and the second conductive layer through the first opening, the second opening and the third opening of the organic insulation layer. An organic isolation layer is formed on the organic insulation layer and covers the organic insulation layer and the tracing layer, where the organic isolation layer has at least one contact opening, and the contact opening is disposed corresponding to the capacitor unit, and exposes a portion of the tracing layer. A pixel electrode is formed on the organic isolation layer, where the pixel electrode is electrically connected to the tracing layer through the contact opening of the organic isolation layer.

In an embodiment of the invention, the manufacturing method of the substrate structure further includes following steps. After the organic insulation layer is formed, a portion of the organic insulation layer is removed to form at least one first opening and at least one second opening, where the first opening exposes a portion of the source, and the second opening exposes a portion of the drain. After the portion of the organic insulation layer is removed, a tracing layer is formed on the organic insulation layer, where the tracing layer is electrically connected to the source and the drain through the first opening and the second opening of the organic insulation layer.

In an embodiment of the invention, the manufacturing method of the substrate structure further includes following steps. When the gate is formed, a first conductive layer is simultaneously formed, where the organic insulation layer covers the first conductive layer, and the first conductive layer and the gate belong to a same film layer. When the tracing layer is formed, a second conductive layer is simultaneously formed, where the second conductive layer and the tracing layer belong to a same film layer. When the portion of the organic insulation layer is removed to form the first opening and the second opening, an insulation layer is further defined, where the insulation layer is located between the first conductive layer and the second conductive layer, and the first conductive layer, the insulation layer and the second conductive layer define a capacitor unit.

In an embodiment of the invention, the semiconductor layer includes a channel layer and an ohmic contact layer located on the channel layer. The ohmic contact layer exposes a portion of the channel layer.

According to the above descriptions, the semiconductor layer in the substrate structure is wrapped by the inorganic insulation layer and the inorganic passivation layer, where the inorganic insulation layer and the inorganic passivation layer are all non-comprehensive film layers, and the organic insulation layer is a comprehensive film layer and covers the flexible substrate exposed by the inorganic insulation layer. Therefore, in the substrate structure of the invention, by configuring the organic insulation layer, device stability and flexibility of the whole substrate structure are enhanced, and by configuring the inorganic insulation layer and the inorganic passivation layer, vapor and oxygen are prevented from entering the semiconductor layer. Moreover, by using the organic insulation layer and the inorganic insulation layer and the inorganic passivation layer in collaboration, when the substrate structure of the invention is bended, crack of the substrate structure is avoided, so as to improve structure reliability and device service life of the substrate structure.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a partial top view of a substrate structure according to an embodiment of the invention.

FIG. 1B is a cross-sectional view of FIG. 1A along a line I-I′.

FIG. 2A to FIG. 2I are cross-sectional views of a manufacturing method of a substrate structure according to an embodiment of the invention.

FIG. 3A to FIG. 3G are top views of the manufacturing method of the substrate structure of FIG. 2A to FIG. 2I.

FIG. 4A to FIG. 4F are cross-sectional views of a manufacturing method of a substrate structure according to another embodiment of the invention.

### DESCRIPTION OF EMBODIMENTS

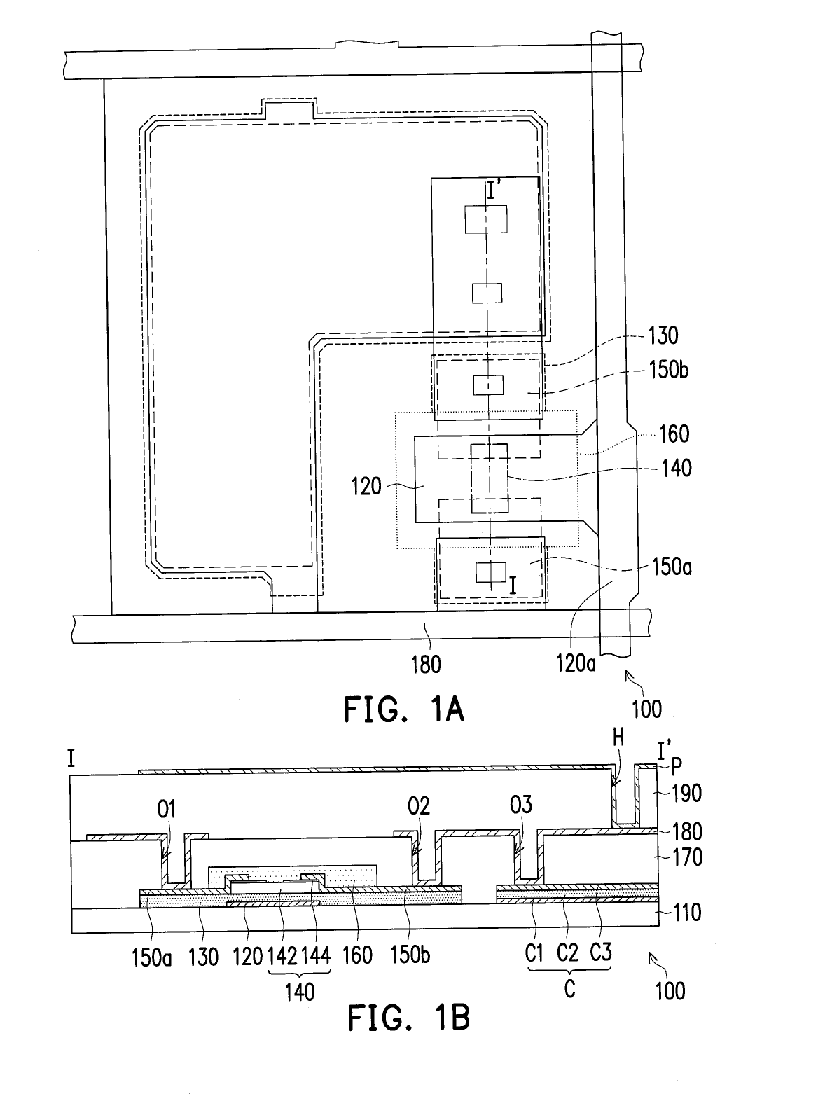

FIG. 1A is a partial top view of a substrate structure according to an embodiment of the invention. FIG. 1B is a cross-sectional view of FIG. 1A along a line I-I′. Referring to FIG. 1A and FIG. 1B, the substrate structure 100 of the present embodiment includes a flexible substrate 110, a gate line 120a, a gate 120, an inorganic insulation layer 130, a semiconductor layer 140, a source 150a, a drain 150b, an inorganic passivation layer 160 and an organic insulation layer 170.

In detail, the gate line 120a is disposed on the flexible substrate 110, and the gate 120 is electrically connected to the gate line 120a and is disposed on the flexible substrate 110. The inorganic insulation layer 130 is disposed on the flexible substrate 110 and covers the gate 120 and exposes a portion of the flexible substrate 110. The semiconductor layer 140 is disposed on the inorganic insulation layer 130 and disposed corresponding to the gate 120. The source 150a and the drain 150b extend from the inorganic insulation layer 130 to the semiconductor layer 140, where the source 150a and the drain 150b expose a portion of the semiconductor layer 140. The inorganic passivation layer 160 is disposed on the source 150a and the drain 150b and covers a portion of the source 150a and a portion of the drain 150b, and directly contacts the semiconductor layer 140 exposed by the source 150a and the drain 150b. The organic insulation layer 170 is disposed on the flexible substrate 110 and covers the source 150a, the drain 150b, the inorganic passivation layer 160 and the flexible substrate 110 exposed by the inorganic insulation layer 130.

In the present embodiment, a material of the flexible substrate 110 includes stainless steel foil, thin glass or plastic thin film (for example, PET, PEN, etc.), though the invention is not limited thereto. The gate 120 is covered by the inorganic insulation layer 130, and an edge of the inorganic insulation layer 130 is aligned to an edge of the source 150a and an edge of the drain 150b, and a material of the inorganic insulation layer 130 is, for example, silicon nitride, silicon oxide or silicon oxynitride, though the invention is not limited thereto. It should be noticed that although the edge of the inorganic insulation layer 130 is aligned to the edge of the source 150a and the edge of the drain 150b, in other embodiment that is not illustrated, the edge of the source 150a and the edge of the drain 150b can also be smaller than the edge of the inorganic insulation layer 130, which is still within a protection range of the invention. Particularly, the inorganic insulation layer 130 does not completely cover the flexible substrate 110, but exposes a portion of the flexible substrate 110. Namely, the inorganic insulation layer 130 of the present embodiment can be regarded as a non-comprehensive film layer.

As shown in FIG. 1B, the semiconductor layer 140 of the present embodiment is disposed corresponding to the gate 120, where an orthogonal projection of the semiconductor layer 140 on the flexible substrate 110 is completely overlapped with an orthogonal projection of the gate 120 on the flexible substrate 110. Here, the semiconductor layer 140 is, for example, an amorphous silicon semiconductor layer, a polycrystalline silicon semiconductor layer or an oxide semiconductor layer, which is not limited by the invention. Moreover, the semiconductor layer 140 of the present embodiment includes a channel layer 142 and an ohmic contact layer 144 located on the channel layer 142, where the ohmic contact layer 144 exposes a portion of the channel layer 142. As shown in FIG. 1B, the edges of the source 150a and the drain 150b are aligned to the edge of the inorganic insulation layer 130. Namely, the source 150a and the drain 150b also expose a portion of the flexible substrate 110. Moreover, the gate 120, the inorganic insulation layer 130, the semiconductor layer 140, the source 150a and the drain 150b of the present embodiment can be regarded as a thin-film transistor.

Moreover, a material of the inorganic passivation layer 160 of the present embodiment is, for example, silicon nitride, silicon oxide or silicon oxynitride, though the invention is not limited thereto. Particularly, the inorganic passivation layer 160 of the present embodiment only covers a portion of the source 150a, a portion of the drain 150b and the semiconductor layer 140 exposed by the source 150a and the drain 150b. Namely, the inorganic passivation layer 160 of the present embodiment can be regarded as a non-comprehensive film layer. As shown in FIG. 1B, the semiconductor layer 140 of the present embodiment is wrapped by the inorganic insulation layer 130 and the inorganic passivation layer 160. Since the inorganic material has a better vapor-proof effect and an oxygen-proof effect, the inorganic insulation layer 130 and the inorganic passivation layer 160 can effectively prevent vapor and oxygen from entering the semiconductor layer 140, by which structure reliability and device service life of the substrate structure 100 are enhanced.

A material of the organic insulation layer 170 of the present embodiment is, for example, polyamide resin (PA) or poly 4-vinyl phenol (PVP), though the invention is not limited thereto. Particularly, the organic insulation layer 170 of the present embodiment comprehensively covers the gate line 120a, the source 150a, the drain 150b, the inorganic passivation layer 160 and the flexible substrate 110 exposed by the inorganic insulation layer 130. Namely, the organic insulation layer 170 of the present embodiment can be regarded as a comprehensive film layer. Since the organic material has better flexibility, by configuring the organic insulation layer 170, besides flexibility of the whole substrate structure 100 is enhanced, devices of the substrate structure 100 can be effectively fixed to increase device stability.

On the other hand, in the present embodiment, since the organic insulation layer 170, the inorganic insulation layer 130 and the inorganic passivation layer 160 are used in collaboration, when the substrate structure 100 of the present embodiment is bended, a problem that vapor and oxygen enter the semiconductor layer due to crack of the conventional inorganic structure layer when it is bended is avoided. In other words, the substrate structure 100 of the present embodiment may have better structure reliability and device service life.

Moreover, the substrate structure 100 of the present embodiment may further include a capacitor unit C, where the capacitor unit C is disposed on the flexible substrate 110, and is configured to store charges to maintain a pixel voltage. In detail, the capacitor unit C includes a first conductive layer C1, an insulation layer C2 and a second conductive layer C3, where the first conductive layer C1 and the gate 120 belong to a same film layer, the insulation layer C2 and the inorganic insulation layer 130 belong to a same film layer, and the second conductive layer C3 and the source 150a and the drain 150b belong to a same film layer. The organic insulation layer 170 covers the capacitor unit C. In detail, the organic insulation layer 170 of the present embodiment has at least one first opening O1, at least one second opening O2 and at least one third opening O3, where the first opening O1 exposes a portion of the source 150a, the second opening O2 exposes a portion of the drain 150b, and the third opening O3 exposes a portion of the second conductive layer C3.

Moreover, the substrate structure 100 of the present embodiment further includes a tracing layer 180, an organic isolation layer 190 and a pixel electrode P. The tracing layer 180 is disposed on the organic insulation layer 170, where the tracing layer 180 is electrically connected to the source 150a, the drain 150b and the second conductive layer C3 through the first opening O1, the second opening O2 and the third opening O3 of the organic insulation layer 170. The organic isolation layer 190 is disposed on the organic insulation layer 170 and covers the organic insulation layer 170 and the tracing layer 180. The organic isolation layer 190 has at least one contact opening H, and the contact opening H is disposed corresponding to the capacitor unit C, and exposes a portion of the tracing layer 180. The pixel electrode P is disposed on the organic isolation layer 190. Namely, the organic isolation layer 190 is used to effectively isolate the pixel electrode P and the tracing layer 180, where the pixel electrode P is electrically connected to the tracing layer 180 through the contact opening H of the organic isolation layer 190.

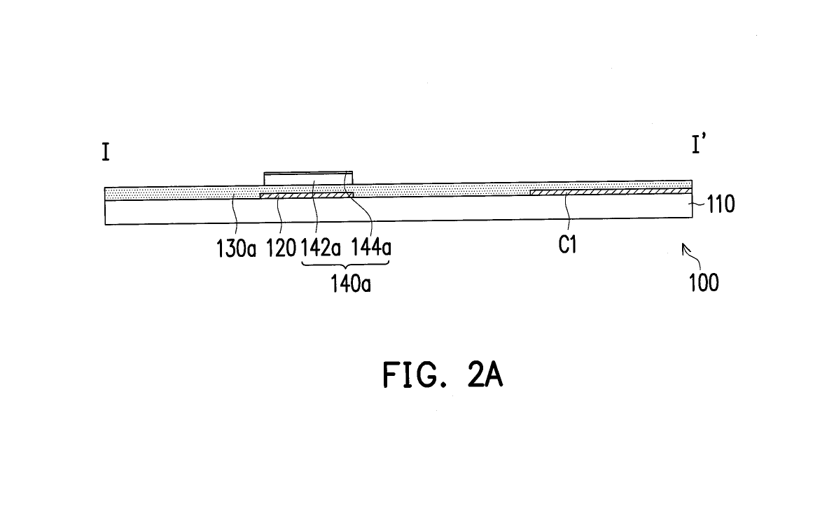

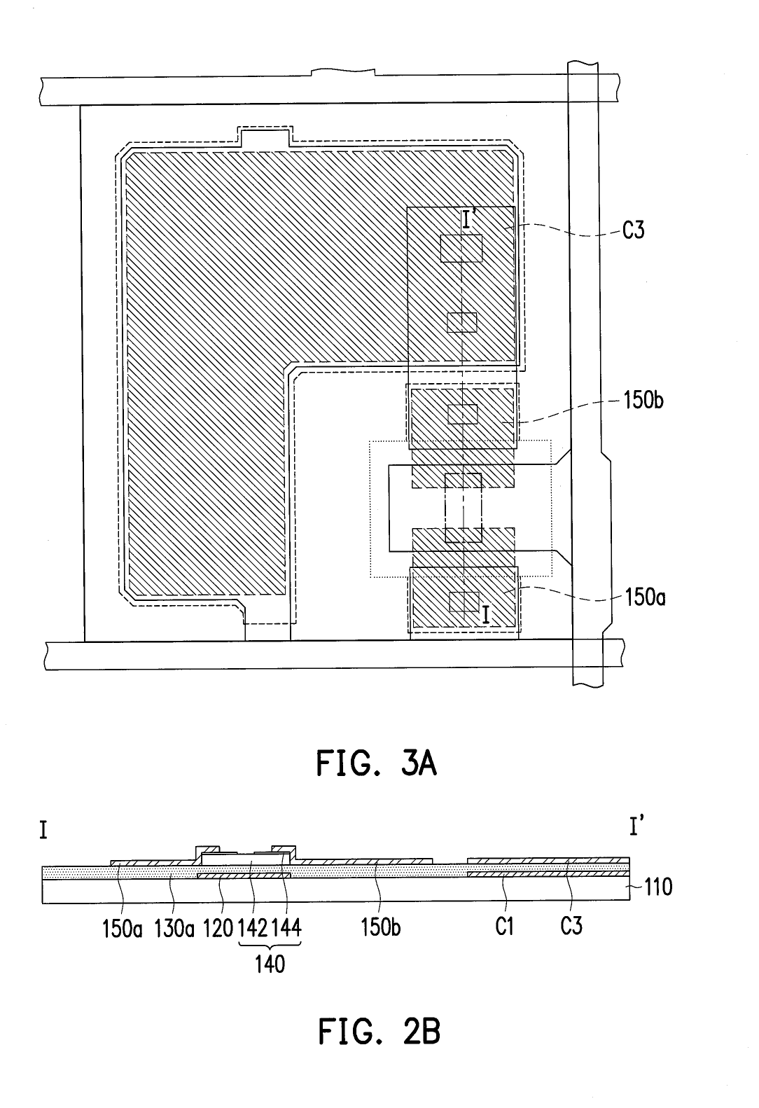

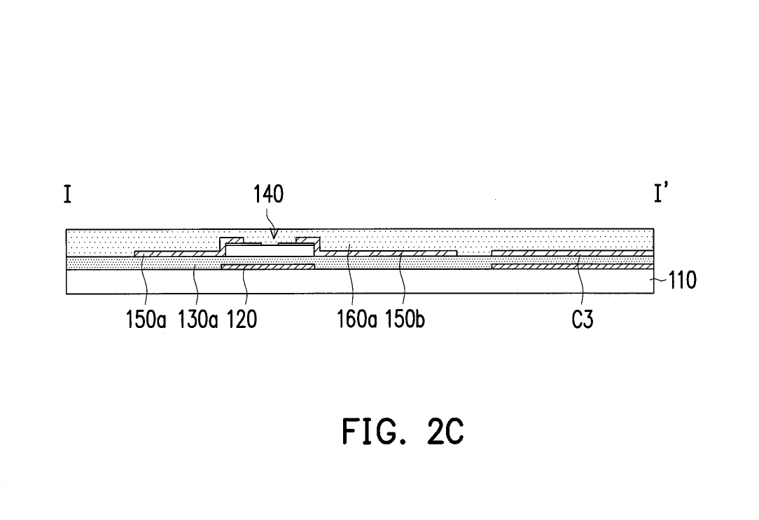

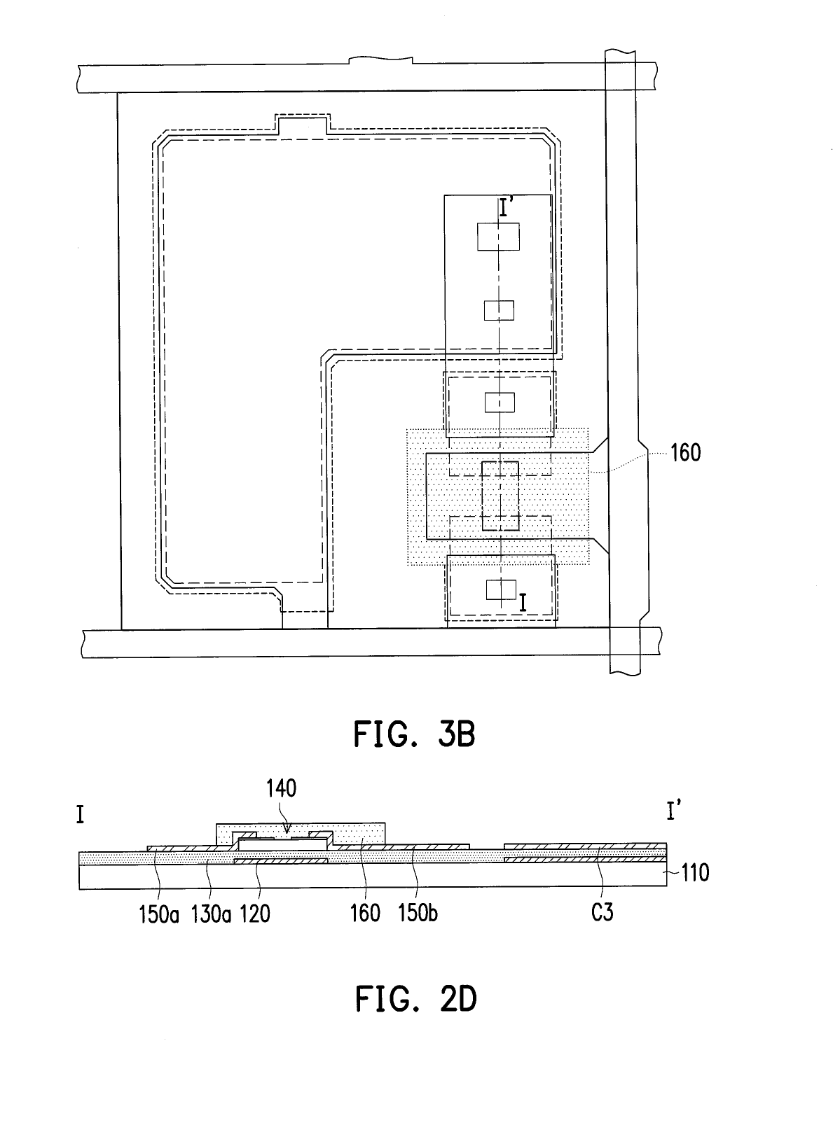

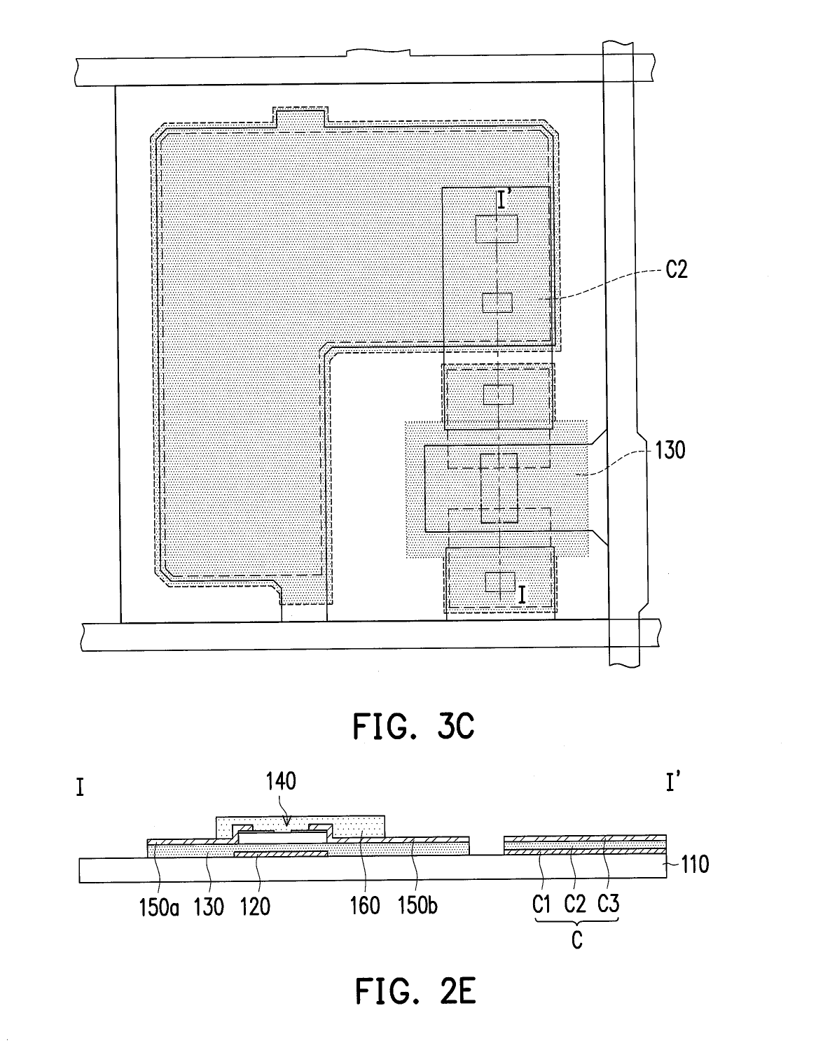

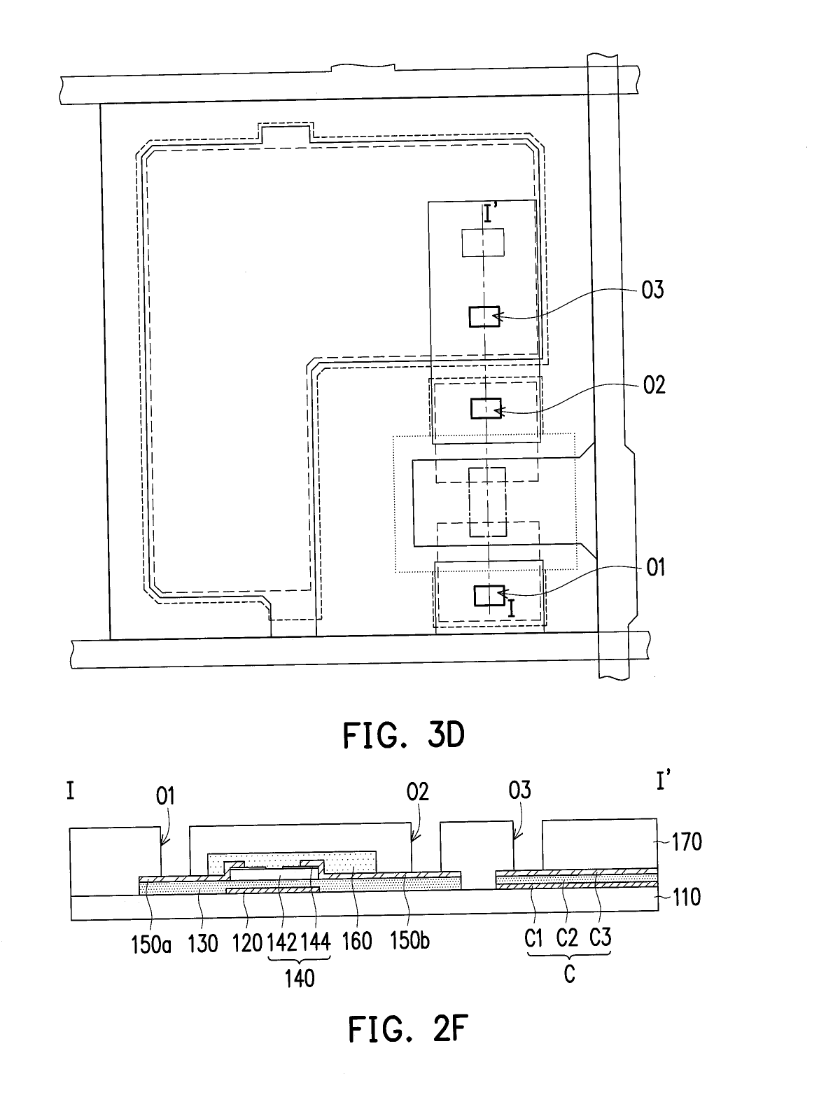

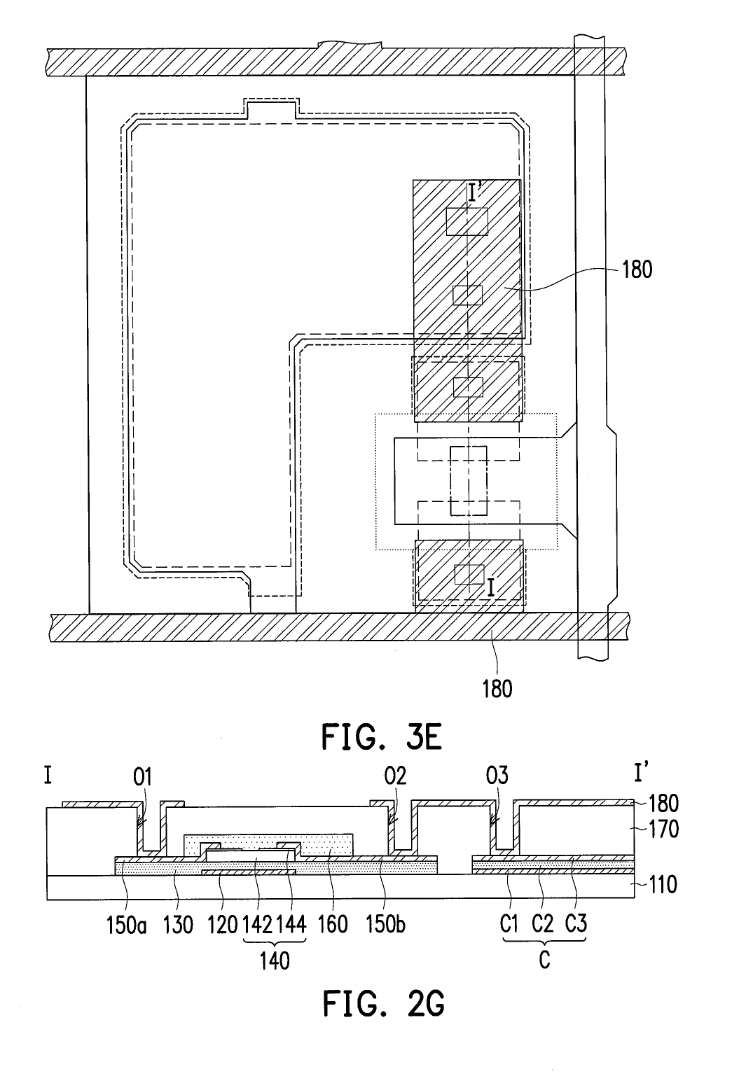

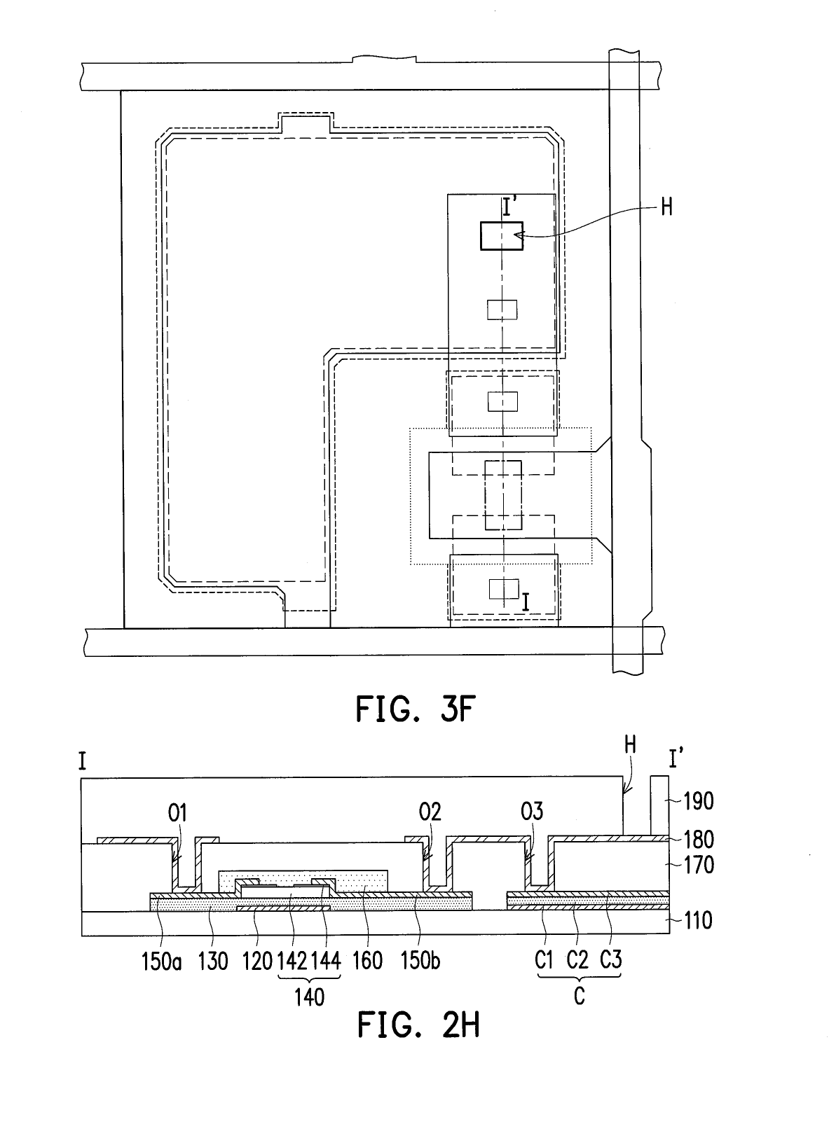

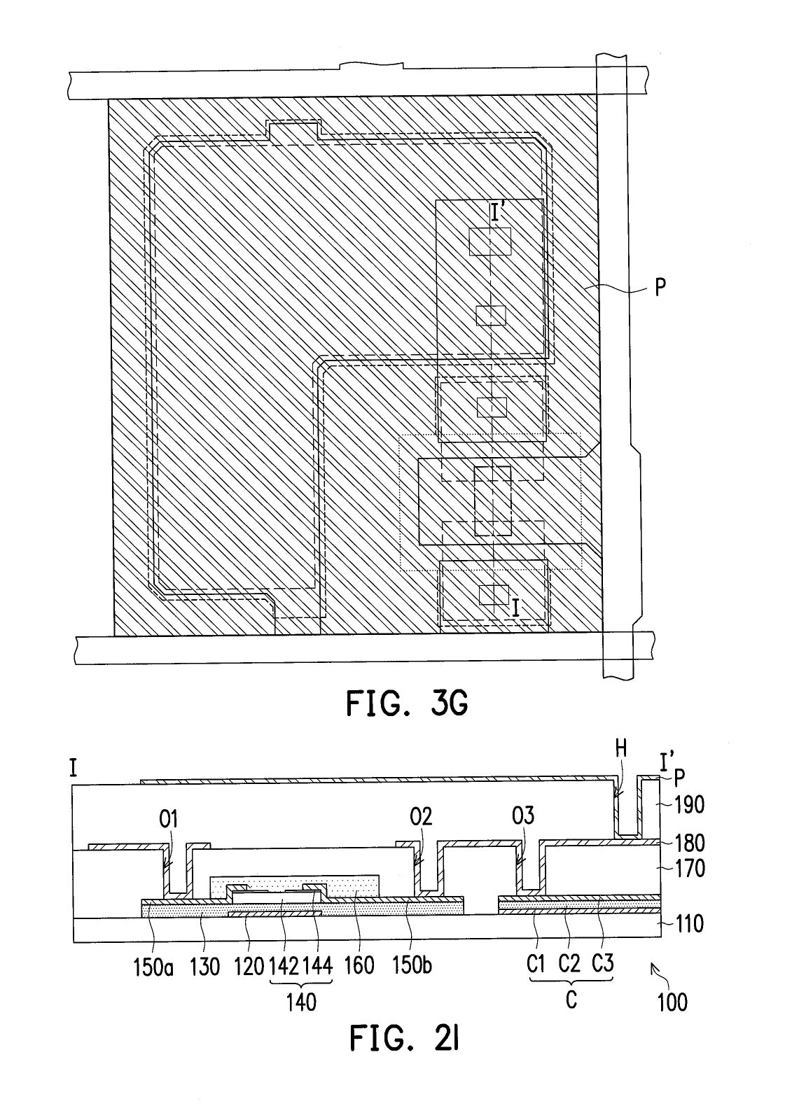

The structure of the substrate structure 100 of the invention is described above, and a manufacturing method of the substrate structure 100 is still not introduced. Therefore, the manufacturing method of the substrate structure 100 is introduced in detail below with reference of FIG. 2A to FIG. 2I and FIG. 3A to FIG. 3G according to the structure of the substrate structure 100 of FIG. 1A and FIG. 1B. It should be noticed that reference numbers of the components and a part of contents of the aforementioned embodiment are also used in the following embodiment, wherein the same reference numbers denote the same or like components, and descriptions of the same technical contents are omitted. The aforementioned embodiment can be referred for descriptions of the omitted parts, and detailed descriptions thereof are not repeated in the following embodiment.

FIG. 2A to FIG. 2I are cross-sectional views of a manufacturing method of a substrate structure according to an embodiment of the invention. FIG. 3A to FIG. 3G are top views of the manufacturing method of the substrate structure of FIG. 2A to FIG. 2I. It should be noticed that FIG. 2A to FIG. 2I are respectively cross-sectional views of FIG. 3A to FIG. 3G along a line I-I′. Referring to FIG. 2A, in the manufacturing method of the substrate structure 100 of the present embodiment, first, the gate 120, an inorganic insulation material layer 130a and a semiconductor material layer 140a are sequentially formed on the flexible substrate 110. The inorganic insulation material layer 130a completely covers the gate 120 and the flexible substrate 110, and the semiconductor material layer 140a is disposed corresponding to the gate 120. Here, the inorganic insulation material layer 130a is a comprehensive film layer, and a material of the inorganic insulation material layer 130a is, for example, silicon nitride, silicon oxide or silicon oxynitride. The semiconductor material layer 140a is composed of a channel layer 142a and an ohmic contact layer 144a located on the channel layer 142a. It should be noticed that when the gate 120 is formed, as shown in FIG. 2A, the first conductive layer Cl is simultaneously formed on the flexible substrate 110, i.e. the first conductive layer Cl and the gate 120 belong to a same film layer, where the inorganic insulation material layer 130a also covers the first conductive layer C1.

Then, referring to FIG. 2B and FIG. 3A, the source 150a and the drain 150b are formed on the organic insulation material layer 130a. The source 150a and the drain 150b extend from the inorganic insulation material layer 130a to the semiconductor material layer 140a (referring to FIG. 2A), and the source 150a and the drain 150b expose a portion of the semiconductor material layer 140a and a portion of the inorganic insulation material layer 130a. It should be noticed that when the source 150a and the drain 150b are formed, the second conductive layer C3 is simultaneously formed, where the second conductive layer C3 is located on the inorganic insulation material layer 130a, and the second conductive layer C3 and the source 150a and the drain 150b belong to a same film layer. Here, the second conductive layer C3 is electrically isolated to the first conductive layer C1 through the inorganic insulation material layer 130a, and the second conductive layer C3 is disposed corresponding to the first conductive layer C1.

Then, referring to FIG. 2B, the portion of the semiconductor material layer 140a exposed by the source 150a and the drain 150b (referring to FIG. 2A) is removed to define the semiconductor layer 140. Here, the semiconductor layer 140 is, for example, an a-Si semiconductor layer, a p-Si semiconductor layer or an oxide semiconductor layer, which is not limited by the invention. In detail, the semiconductor layer 140 of the present embodiment includes a channel layer 142 and a homic contact layer 144 located on the channel layer 142, where the ohmic contact layer 144 exposes a portion of the channel layer 142. The portion of the semiconductor material layer 140a is, for example, removed through an etching process. It should be noticed that a purpose of removing the portion of the semiconductor material layer 140 is to avoid current leakage.

Then, referring to FIG. 2C, an inorganic passivation material layer 160a is formed on the source 150a and the drain 150b, where the inorganic passivation material layer 160a covers the source 150a and the drain 150b, the semiconductor layer 140 exposed by the source150a and the drain 150b, and a portion of the inorganic insulation material layer 130a. As shown in FIG. 2C, the inorganic passivation material layer 160a also covers the second conductive layer C3. In other words, the inorganic passivation material layer 160a can be regarded as a comprehensive film layer.

Then, referring to FIG. 2D and FIG. 3B, a portion of the inorganic passivation material layer 160a is removed to form the inorganic passivation layer 160. Now, the inorganic passivation layer 160 is disposed on the source 150a and the drain 150b and covers a portion of the source 150a and a portion of the drain 150b, and directly contact the semiconductor layer 140 exposed by the source 150a and the drain 150b. Namely, the inorganic passivation layer 160 does not cover the second conductive layer C3 and the inorganic insulation material layer 130a. The portion of the inorganic passivation material layer 160a is, for example, removed through an etching process.

Then, referring to FIG. 2E and FIG. 3C, the inorganic insulation material layer 130a exposed by the source 150a and the drain 150b is removed to expose a portion of the flexible substrate 110 and define the inorganic insulation layer 130. Here, if the source 150a and the drain 150b are taken as an etching mask of the inorganic insulation layer 130, the edge of the inorganic insulation layer 130 is aligned to the edge of the source 150a and the edge of the drain 150b, and if other photoresist process is used as the etching process, the edge of the source 150a and the edge of the drain 150b are probably smaller than the edge of the inorganic insulation layer 130. In other words, the edge of the source 150a and the edge of the drain 150b do not exceed the edge of the inorganic insulation layer 130. The method for removing the inorganic insulation material layer 130a exposed by the source 150a and the drain 150b is, for example, the etching process. It should be noticed that when the inorganic insulation material layer 130a exposed by the source 150a and the drain 150b is removed, the insulation layer C2 is defined, where the insulation layer C2 is located between the first conductive layer C1 and the second conductive layer C3, and the first conductive layer C1, the insulation layer C2 and the second conductive layer C3 define the capacitor unit C.

Then, referring to FIG. 2F and FIG. 3D, the inorganic insulation layer 170 is formed on the flexible substrate 110, wherein the organic insulation layer 170 covers the source 150a, the drain 150b, the inorganic passivation layer 160, the flexible substrate 110 exposed by the inorganic insulation layer 130 and the capacitor structure C. Then, a portion of the organic insulation layer 170 is removed to form the at least one first opening O1, the at least one second opening O2 and the at least one third opening O3, where the first opening O1 exposes a portion of the source 150a, the second opening O2 exposes a portion of the drain 150b, and the third opening O3 exposes a portion of the second conductive layer C3. Here, as shown in FIG. 3D, the organic insulation layer 170 is a comprehensive film layer, and only has the first opening O1, the second opening O2 and the third opening O3 respectively exposing the source 150a, the drain 150b and the second conductive layer C3. Here, if the organic insulation layer 170 adopts a photosensitive material, a portion of the organic insulation layer 170 can be removed through an exposing and developing method. Alternatively, if the organic insulation layer 170 adopts a non-photosensitive material, the portion of the organic insulation layer 170 can be removed through a yellow etching method.

Then, referring to FIG. 2G and FIG. 3E, the tracing layer 180 is formed on the organic insulation layer 170, where the tracing layer 180 is electrically connected to the source 150a, the drain 150b and the second conductive layer C3 through the first opening O1, the second opening O2 and the third opening O3 of the organic insulation layer 170.

Then, referring to FIG. 2H and FIG. 3F, the organic isolation layer 190 is formed on the organic insulation layer 170 and covers the organic insulation layer 170 and the tracing layer 180, where the organic isolation layer 190 has at least one contact opening H, and the contact opening H is disposed corresponding to the capacitor unit C, and exposes a portion of the tracing layer 180. Here, as shown in FIG. 3F, the organic isolation layer 190 is a comprehensive film layer, and only has the contact opening H exposing the tracing layer 180.

Finally, the pixel electrode P is formed on the organic isolation layer 190, where the pixel electrode P is electrically connected to the tracing layer 180 through the contact opening H of the organic isolation layer 190. Now, fabrication of the substrate structure 100 is completed.

It should be noticed that a composition pattern of the capacitor unit C is not limited by the invention, and although the capacitor unit C is composed of the first conductive layer C1 formed by the same film layer with that of the gate 120, the insulation layer C2 formed by the same film layer with that of the inorganic insulation layer 130 and the second conductive layer C3 formed by the same film layer with that of the source 150a and the drain 150b in the present embodiment, in other embodiments, the capacitor unit may have other composition patterns.

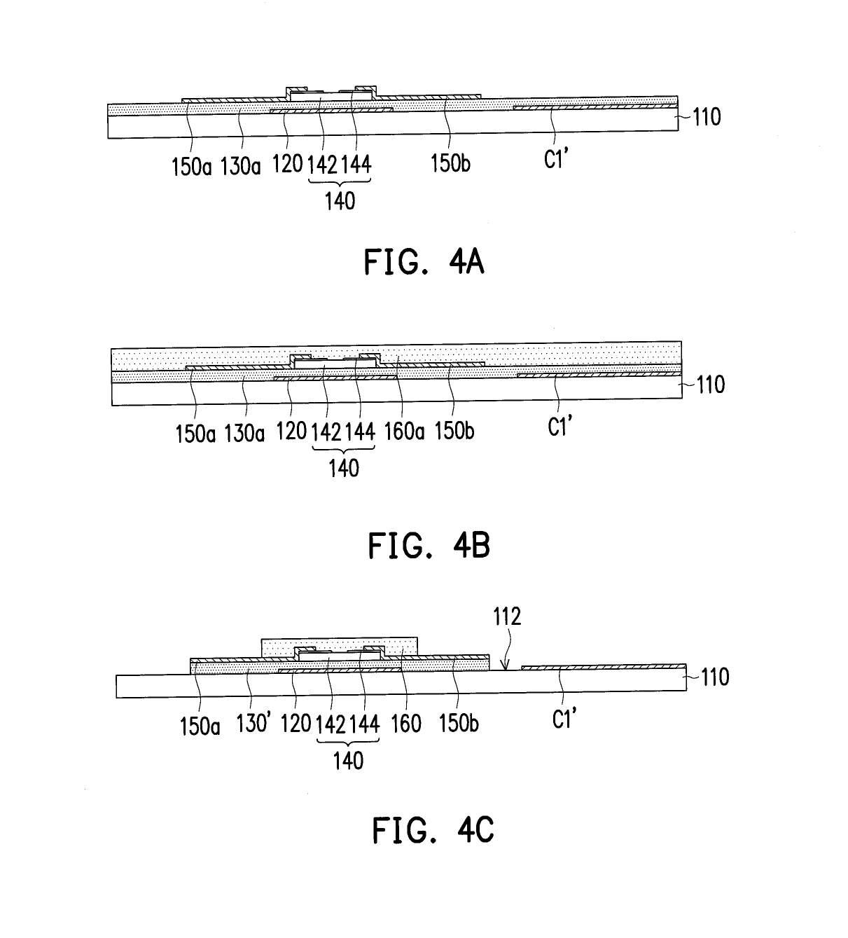

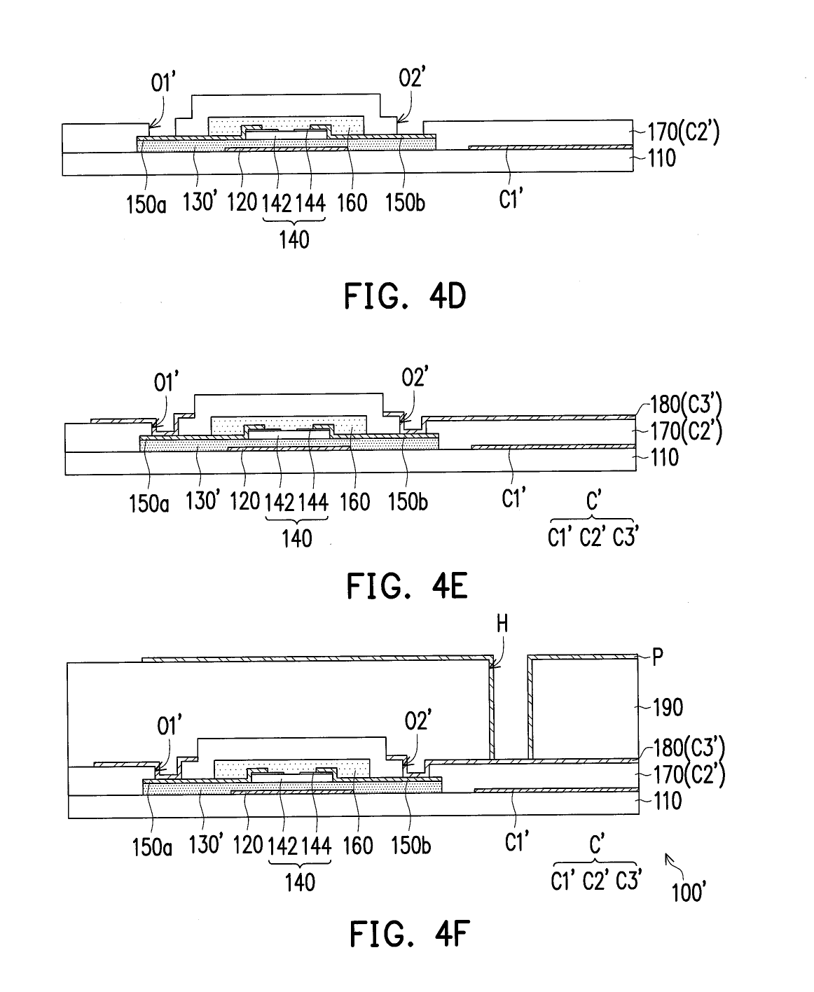

In detail, FIG. 4A to FIG. 4F are cross-sectional views of a manufacturing method of a substrate structure according to another embodiment of the invention. Referring to FIG. 4A, when the gate 120 is formed, a first conductive layer C1′ is simultaneously formed, where the inorganic insulation material layer 130a covers the first conductive layer C1′, and the first conductive layer C1′ and the gate 120 belong to a same film layer.

Then, referring to FIG. 4B, when the inorganic passivation material layer 160a is formed, the inorganic passivation material layer 160a simultaneously covers the source 150a, the drain 150b, the semiconductor layer 140 exposed by the source 150a and the drain 150b and the inorganic insulation material layer 130a.

Then, referring to FIG. 4C, a portion of the inorganic passivation material layer 160a is removed, and the inorganic insulation material layer 130a exposed by the source 150a and the drain 150b is removed to form the inorganic passivation layer 160 and the inorganic insulation layer 130′. Now, the inorganic insulation layer 130′ does not cover the first conductive layer C1′, namely, the first conductive layer C1′ is completely exposed by the inorganic insulation layer 130′. Moreover, the inorganic passivation layer 160 is disposed on the source 150a and the drain 150b and covers a portion of the source 150a and a portion of the drain 150b, and directly contacts the semiconductor layer 140 exposed by the source 150a and the drain 150b. Moreover, the inorganic insulation layer 130′ also exposes a portion of surface 112 of the flexible substrate 110.

Then, referring to FIG. 4D, the organic insulation layer 170 is formed on the flexible substrate 110, where the organic insulation layer 170 covers the source 150a, the drain 150b, the inorganic passivation layer 160, the inorganic insulation layer 130′, the flexible substrate 110 exposed by the inorganic insulation layer 130′ and the first conductive layer C1′. Then, a portion of the organic insulation layer 170 is removed to form at least one first opening O1′ and at least one second opening O2′, where the first opening O1′ exposes a portion of the source 150a, and the second opening O2′ exposes a portion of the drain 150b. Here, when the portion of the organic insulation layer 170 is removed to form the first opening O1′ and the second opening O2′, an insulation layer CT is further defined, where the insulation layer C2′ is located on the first conductive layer C1′, and the insulation layer C2′ covers the first conductive layer C1′, and the insulation layer C2′ and the organic insulation layer 170 belong to a same film layer.

Then, referring to FIG. 4E, the tracing layer 180 is formed on the organic insulation layer 170, where the tracing layer 180 is electrically connected to the source 150a and the drain 150b through the first opening O1′ and the second opening O2′ of the organic insulation layer 170. Here, when the tracing layer 180 is formed, a second conductive layer C3′ is simultaneously formed, where the second conductive layer C3′ and the tracing layer 180 belong to a same film layer, and the second conductive layer C3′ is located on the insulation layer C2′, and the first conductive layer C1′, the insulation layer C2′ and the second conductive layer C3′ define a capacitor unit C′.

Finally, referring to FIG. 4F, the organic isolation layer 190 is formed on the organic insulation layer 170 and covers the organic insulation layer 170, the tracing layer 180 and the second conductive layer C3′ of the capacitor unit C′, where the organic isolation layer 190 has at least one contact opening H, and the contact opening H is disposed corresponding to the capacitor unit C′, and the contact opening H exposes a portion of the second conductive layer C3′. Here, the organic isolation layer 190 is a comprehensive film layer, and only has the contact opening H exposing the second conductive layer C3′. Finally, the pixel electrode P is formed on the organic isolation layer 190, where the pixel electrode P is electrically connected to the second conductive layer C3′ through the contact opening H of the organic isolation layer 190. Now, fabrication of the substrate structure 100′ is completed.

In summary, the semiconductor layer in the substrate structure is wrapped by the inorganic insulation layer and the inorganic passivation layer, where the inorganic insulation layer and the inorganic passivation layer are all non-comprehensive film layers, and the organic insulation layer is a comprehensive film layer and covers the flexible substrate exposed by the inorganic insulation layer. Therefore, in the substrate structure of the invention, by configuring the organic insulation layer, device stability and flexibility of the whole substrate structure are enhanced, and by configuring the inorganic insulation layer and the inorganic passivation layer, vapor and oxygen are prevented from entering the semiconductor layer. Moreover, by using the organic insulation layer and the inorganic insulation layer and the inorganic passivation layer in collaboration, when the substrate structure of the invention is bended, crack of the substrate structure is avoided, so as to improve structure reliability and device service life of the substrate structure.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A substrate structure, comprising:
a flexible substrate;
a gate line, disposed on the flexible substrate;
a gate, electrically connected to the gate line, and disposed on the flexible substrate;
an inorganic insulation layer, disposed on the flexible substrate, and covering the gate and exposing a portion of the flexible substrate;
a semiconductor layer, disposed on the inorganic insulation layer and disposed corresponding to the gate;
a source and a drain, extending from the inorganic insulation layer to the semiconductor layer, wherein the source and the drain expose a portion of the semiconductor layer;
an inorganic passivation layer, disposed on the source and the drain and covering a portion of the source and a portion of the drain, and directly contacting the semiconductor layer exposed by the source and the drain; and
an organic insulation layer, disposed on the flexible substrate, and covering the source, the drain, the inorganic passivation layer and the flexible substrate exposed by the inorganic insulation layer.

2. The substrate structure as claimed in claim 1, further comprising:
a capacitor unit, disposed on the flexible substrate, and comprising a first conductive layer, an insulation layer and a second conductive layer, wherein the first conductive layer and the gate belong to a same film layer, the insulation layer and the inorganic insulation layer belong to a same film layer, the second conductive layer and the source and the drain belong to a same film layer, and the organic insulation layer covers the capacitor unit.

3. The substrate structure as claimed in claim 2, wherein the organic insulation layer has at least one first opening, at least one second opening and at least one third opening, the first opening exposes a portion of the source, the second opening exposes a portion of the drain, and the third opening exposes a portion of the second conductive layer.

4. The substrate structure as claimed in claim 3, further comprising:
a tracing layer, disposed on the organic insulation layer, wherein the tracing layer is electrically connected to the source, the drain and the second conductive layer through the first opening, the second opening and the third opening of the organic insulation layer;
an organic isolation layer, disposed on the organic insulation layer and covering the organic insulation layer and the tracing layer, wherein the organic isolation layer has at least one contact opening, and the contact opening is disposed corresponding to the capacitor unit, and exposes a portion of the tracing layer; and
a pixel electrode, disposed on the organic isolation layer, wherein the pixel electrode is electrically connected to the tracing layer through the contact opening of the organic isolation layer.

5. The substrate structure as claimed in claim 1, wherein the organic insulation layer has at least one first opening and at least one second opening, the first opening exposes a portion of the source, and the second opening exposes a portion of the drain.

6. The substrate structure as claimed in claim 5, further comprising:
a tracing layer, disposed on the organic insulation layer, wherein the tracing layer is electrically connected to the source and the drain through the first opening and the second opening of the organic insulation layer; and
a capacitor unit, disposed on the flexible substrate, and comprising a first conductive layer, an insulation layer and a second conductive layer, wherein the first conductive layer and the gate belong to a same film layer, the insulation layer and the organic insulation layer belong to a same film layer, and the second conductive layer and the tracing layer belong to a same film layer.

7. The substrate structure as claimed in claim 1, wherein the organic insulation layer covers the gate line.

8. The substrate structure as claimed in claim 1, wherein the semiconductor layer comprises a channel layer and an ohmic contact layer located on the channel layer, and the ohmic contact layer exposes a portion of the channel layer.

9. A manufacturing method of a substrate structure, comprising:
sequentially forming a gate electrically connected to a gate line, an inorganic insulation material layer and a semiconductor material layer on a flexible substrate, wherein the inorganic insulation material layer completely covers the gate and the flexible substrate, and the semiconductor material layer is disposed corresponding to the gate;
forming a source and a drain on the organic insulation material layer, wherein the source and the drain extend from the inorganic insulation material layer to the semiconductor material layer, and the source and the drain expose a portion of the semiconductor material layer and a portion of the inorganic insulation material layer;
removing the portion of the semiconductor material layer exposed by the source and the drain to define a semiconductor layer;
forming an inorganic passivation layer on the source and the drain, wherein the inorganic passivation layer covers a portion of the source and a portion of the drain, and directly contacts the semiconductor layer;
removing the inorganic insulation material layer after the inorganic passivation layer is formed, so as to expose a portion of the flexible substrate and define an inorganic insulation layer; and
forming an organic insulation layer on the flexible substrate, wherein the organic insulation layer covers the source, the drain, the inorganic passivation layer and the flexible substrate exposed by the inorganic insulation layer.

10. The manufacturing method of the substrate structure as claimed in claim 9, wherein the step of forming the inorganic passivation layer on the source and the drain comprises:
forming an inorganic passivation material layer on the source and the drain, wherein the inorganic passivation material layer covers the source, the drain, the semiconductor layer exposed by the source and the drain and a portion of the inorganic insulation material layer; and
removing a portion of the inorganic passivation material layer to form the inorganic passivation layer.

11. The manufacturing method of the substrate structure as claimed in claim 9, further comprising:
simultaneously forming a first conductive layer when the gate is formed, wherein the inorganic insulation material layer covers the first conductive layer, and the first conductive layer and the gate belong to a same film layer;
simultaneously forming a second conductive layer when the source and the gate are formed, wherein the second conductive layer is located on the inorganic insulation material layer, and the second conductive layer and the source and the drain belong to a same film layer;
defining an insulation layer when the inorganic insulation material layer exposed by the source and the drain is removed, wherein the insulation layer is located between the first conductive layer and the second conductive layer, and the first conductive layer, the insulation layer and the second conductive layer define a capacitor unit; and
covering the capacitor unit by the organic insulation layer when the organic insulation layer is formed on the flexible substrate.

12. The manufacturing method of the substrate structure as claimed in claim 11, further comprising:
removing a portion of the organic insulation layer after the organic insulation layer is formed, so as to form at least one first opening, at least one second opening and at least one third opening, wherein the first opening exposes a portion of the source, the second opening exposes a portion of the drain, and the third opening exposes a portion of the second conductive layer.

13. The manufacturing method of the substrate structure as claimed in claim 12, further comprising:
forming a tracing layer on the organic insulation layer after a portion of the organic insulation layer is removed, wherein the tracing layer is electrically connected to the source, the drain and the second conductive layer through the first opening, the second opening and the third opening of the organic insulation layer;
forming an organic isolation layer on the organic insulation layer to cover the organic insulation layer and the tracing layer, wherein the organic isolation layer has at least one contact opening, and the contact opening is disposed corresponding to the capacitor unit, and exposes a portion of the tracing layer; and
forming a pixel electrode on the organic isolation layer, wherein the pixel electrode is electrically connected to the tracing layer through the contact opening of the organic isolation layer.

14. The manufacturing method of the substrate structure as claimed in claim 9, further comprising:
removing a portion of the organic insulation layer after the organic insulation layer is formed, so as to form at least one first opening and at least one second opening, wherein the first opening exposes a portion of the source, and the second opening exposes a portion of the drain; and
forming a tracing layer on the organic insulation layer after the portion of the organic insulation layer is removed, wherein the tracing layer is electrically connected to the source and the drain through the first opening and the second opening of the organic insulation layer.

15. The manufacturing method of the substrate structure as claimed in claim 14, further comprising:
simultaneously forming a first conductive layer when the gate is formed, wherein the organic insulation layer covers the first conductive layer, and the first conductive layer and the gate belong to a same film layer;
simultaneously forming a second conductive layer when the tracing layer is formed, wherein the second conductive layer and the tracing layer belong to a same film layer; and
further defining an insulation layer when the portion of the organic insulation layer is removed to form the first opening and the second opening, wherein the insulation layer is located between the first conductive layer and the second conductive layer, and the first conductive layer, the insulation layer and the second conductive layer define a capacitor unit.

16. The manufacturing method of the substrate structure as claimed in claim 9, wherein the semiconductor layer comprises a channel layer and an ohmic contact layer located on the channel layer, and the ohmic contact layer exposes a portion of the channel layer.
